(19) United States
(12) Patent Application Publication
(10) Pub. No.: US 2005/0154953 A1
(43) Pub. Date: Jul. 14, 2005

(54) Multiple function pattern generator and comparator having self-seeding test function

(76) Inventor: Allen Curtis Norskog, Fort Collins, CO (US)

Correspondence Address: AGILENT TECHNOLOGIES, INC.;Legal Department, DL 429, Intellectual Property Administration, P.O. Box 7599, Loveland, CO, 80537-0599, US

(21) Appl. No.: 10/755,510

(22) Filed: Jan. 12, 2004

(51) Int. Cl. G06F 11/00; G01R 31/28

(52) U.S. Cl. 714/738

(57) ABSTRACT

A multiple function pattern generator for a serializer/deserializer circuit located on an integrated circuit (IC), comprises a pattern generator in a communications channel, the pattern generator configured to develop a plurality of test patterns and configured to receive the output of the communications channel and user data based on pattern selection and user data, and a comparator configured to receive the output of the communication channel and the output of the pattern generator, where the pattern generator self seeds with the user data, and where the user data comprises a fixed length bit test pattern.

### BACKGROUND

Integrated circuits (IC) and, more specifically, application specific integrated circuits (ASICs) that are used in communication systems are becoming more and more complex, and are operating at ever increasing data rates. Accordingly, the increasing data rates necessitate the ability to test the communication circuit under increasingly stringent parameters.

Many communication channels are structured to convert parallel data to serial data for communication over a serial communication link. A serial communication link has advantages over a parallel communication link, particularly for long distance communication methodologies, such as long distance optical fiber communication systems and satellite communication systems. Generally, the parallel data is “serialized” for transmission over the serial communication link and “deserialized” at the receiver, to yield the original parallel data. Such a communication system uses what is referred to as a “SerDes,” or a serializer/deserializer circuit.

Several factors affect the quality of the transmission. These factors include the type of transmission medium, distance (e.g., length of the cable), electrical interference, and the quality of electrical shielding of the communication medium. In addition, the data is often coded for transmission by increasing the quantity of logic “1” to logic “0” signal transitions. The signal transitions between different bits of data are used in “clock recovery” circuits in the receiver to make it easier for the receiving circuit to maintain synchronization with the received data.

Several test methods for determining the quality of transmission have been developed. One frequently employed method is to use a pseudo-random binary sequence, referred to as a PRBS pattern. A PRBS pattern based on the “x6+x7+1” polynomial is built into many SerDes circuits and is referred to as a PRBS-7 test pattern generator. It provides a pattern that repeats every (2\hat{ }7)-1=127 bits. This pattern sequence is sufficiently long to appear quite random, but not so long to prevent easy testing and generation with a relatively small amount of circuitry. The PRBS-7 test pattern also “stresses” a communication circuit harder than when in typical use because there are some parts of the pattern sequence with fewer transitions than typically used during normal data communication. The (2\hat{ }7)-1 pattern (or PRBS-7) pattern has a maximum run of seven consecutive logic 1's and a maximum run of six consecutive logic 0's. The number of consecutive bits without a bit transition is commonly called the run length. The “8b10b” (8-bit to 10-bit) coding that is very commonly used in such communication circuits will have a maximum run length of only 5 bits (of either 1's or 0's), so the PRBS-7 test pattern is more stressful on the communication circuit than data communicated using the 8b10b coding scheme.

In a previous SerDes implementation, an additional pattern mode was added that allowed testing longer run lengths up to ten bits long. This was accomplished using a 10-bit “user” register that could be loaded with any 10-bit value desired. Both the pattern generator in the transmitter and receiver could be loaded with this value. The transmitter sends this value and the receiver compares the received pattern with the user defined pattern previously loaded. However, repeatedly sending a 10-bit value can only test run lengths up to 9 bits long because if all 10 bits are the same, then the run length is longer than 10 bits. To test lengths up to 10 bits an “alternate inverse” mode can be used. In this mode the 10-bit word would be sent followed by the inverse of the word. In this way a 20-bit pattern is actually generated. One useful feature of this 20-bit pattern is that the pattern is “balanced” with an equal number of 1's and 0's. Some communication circuits can be sensitive if the data sent is not balanced. For this reason the “8b10b” code mentioned earlier also codes data so that the data transmitted is balanced.

As information needs continue to increase, it is desirable to find ways to send more data more quickly. One way is to increase the data rate. Another way is to find more efficient ways to send the data. The previously mentioned “8b10b” code has a 25% efficiency overhead in that it uses 10 bit times to send 8 bits of data. One way to improve efficiency is to use other coding techniques with a smaller overhead penalty. However, improvements in coding efficiency typically result in longer possible bit run lengths. These run lengths can be longer than those tested with the PRBS-7 pattern or even the 10-bit test capabilities previously used.

Therefore, it is desirable to have a way to test higher data rate communication channels, while minimizing the amount of test circuitry.

### SUMMARY

Embodiments of the multiple function pattern generator and comparator having self-seeding test function include a pattern generator in a communications channel, the pattern generator configured to develop a plurality of test patterns and configured to receive the output of the communications channel and user data based on pattern selection and user data. The multiple function pattern generator and comparator having self-seeding test function also includes a comparator configured to receive the output of the communication channel and the output of the pattern generator, where the pattern generator self seeds with the user data, and where the user data comprises a fixed length bit test pattern.

Other systems, methods, features, and advantages of the invention will be or become apparent to one with skill in the art upon examination of the following figures and detailed description. It is intended that all such additional systems, methods, features, and advantages be included within this description, be within the scope of the invention, and be protected by the accompanying claims.

### BRIEF DESCRIPTION OF THE FIGURES

The multiple function pattern generator and comparator having self-seeding test function can be better understood with reference to the following figures. The components within the figures are not necessarily to scale, emphasis instead being placed upon clearly illustrating the principles of the system and method. Moreover, in the figures, like reference numerals designate corresponding parts throughout the different views.

FIG. 1 is a block diagram illustrating a communication environment in which the multiple function pattern generator and comparator having self seeding test function operates.

FIG. 2 is a block diagram illustrating one of the pattern generators of FIG. 1.

FIG. 3 is a block diagram illustrating the function logic and selection element of FIG. 2.

FIG. 4 is a block diagram illustrating the register and the function logic and selection element of FIG. 2 configured to load PRBS-31 pattern generator data in the transmitter.

FIG. 5 is a block diagram illustrating the register and the function logic and selection element of FIG. 2 configured to run the data loaded in FIG. 4.

FIG. 6 is a block diagram illustrating the register and the function logic and selection element of FIG. 2 configured to load user defined fixed length data in the transmitter.

FIG. 7 is a block diagram illustrating the register and the function logic and selection element of FIG. 2 configured to run the user defined fixed length data loaded in FIG. 6.

FIG. 8 is a block diagram illustrating the register and the function logic and selection element of FIG. 2 in an alternative embodiment that can be used in the receiver pattern generator.

FIG. 9 is a block diagram illustrating the register and the function logic and selection element of FIG. 2 configured with the comparator of FIG. 1 in a user defined 40-bit “load to error” mode in the receiver.

FIG. 10 is a block diagram illustrating the register and the function logic and selection element of FIG. 2 configured to run PRBS-31 pattern data in a “load till error” mode in the receiver.

### DETAILED DESCRIPTION

The multiple function pattern generator and comparator having self-seeding test function, which will be referred to as the multiple function pattern generator, can be implemented and integrated onto an existing transceiver integrated circuit (IC). Further, multiple iterations of the multiple function pattern generator can be implemented on a single integrated circuit. While the multiple function pattern generator will be described below using specific hardware elements, modules and devices, the multiple function pattern generator can be implemented using a variety of different technology. Further still, while described below using a hardware implementation, portions of the multiple function pattern generator can be implemented partially or completely in software.

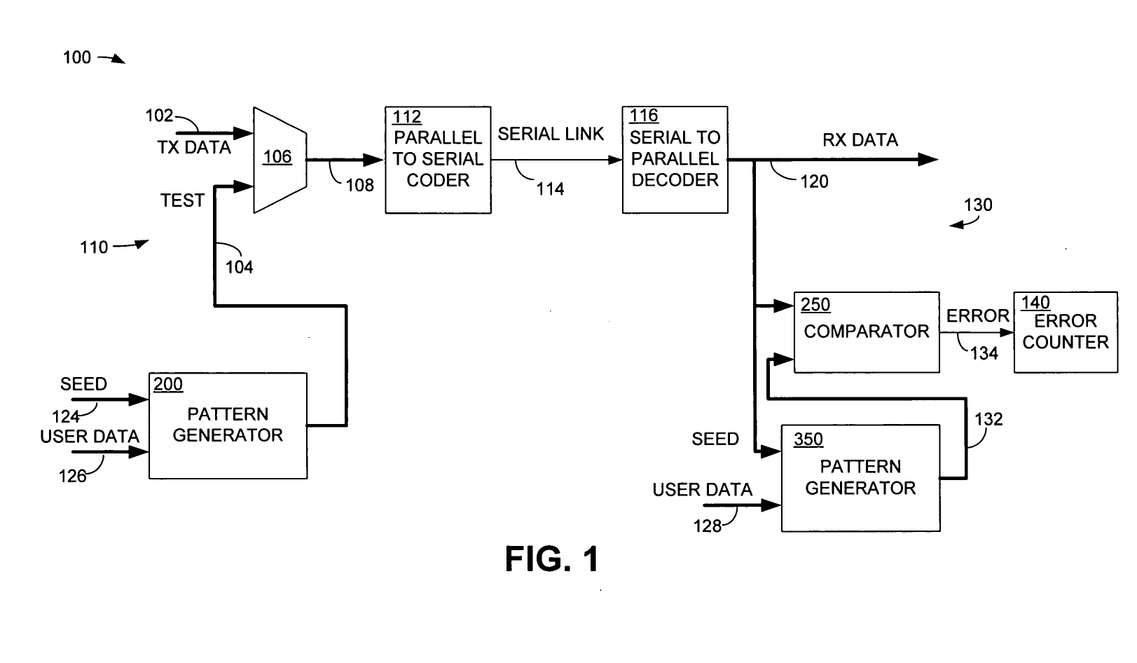

FIG. 1 is a block diagram illustrating a communication environment in which the multiple function pattern generator operates. The communication environment 100 includes a serial communication link 114 over which communication data is exchanged between a transceiver 110 and a transceiver 130. In the communication environment 100 shown in FIG. 1, data is transmitted from parallel to serial coder 112 and received by serial to parallel decoder 116. However, it is understood that the transceivers 110 and 130 each include a transmitter and a receiver, each respectively including a parallel to serial coder and a serial to parallel decoder, thus allowing data to be transmitted in a direction opposite that shown in FIG. 1. The communication environment 100 includes a pattern generator 200, which can be a PRBS pattern generator and which receives seed data on connection 124 and user data on connection 126. The output of the pattern generator 200 is supplied via connection 104 as a test input to a multiplexer 106. The multiplexer 106 receives transmit data via connection 102. The output of the multiplexer 106 via connection 108 is coupled to the parallel to serial coder 112. Whether the output of the multiplexer 106 is the transmit data on connection 102 or the test data on connection 104 is determined by a control signal (not shown) supplied to the multiplexer 106. The parallel to serial coder 112 takes the parallel data on connection 108 and serializes the data for transmission over the serial communication link 114. The connections 124, 126, 104, 102, 108 are shown as heavy arrows to denote parallel data.

The serial to parallel decoder 116 receives the serial data from connection 114 and converts the serial data into parallel data on connection 120. The parallel data on connection 120 is the output of the transceiver 130 and is also the input to a pattern generator 350 and to a comparator 250. The pattern generator 200 in the transmit path is similar to the pattern generator 350 in the receive path, but, as will be described below, can be configured differently, depending on whether it is operating in a transmit mode or in a receive mode, and depending on the mode of pattern generation operation.

The pattern generator 350 receives user data via connection 128 and seed data via connection 120. In other words, the output of the serial-to-parallel decoder 116 may be used to seed the pattern generator 350 in the receiver. The output of the pattern generator 350 on connection 132 is supplied to the comparator 250. The comparator 250 compares the output of the pattern generator 350 with the parallel data (i.e., the seed data) on connection 120 and provides, on connection 134, an error signal denoting whether the received data on connection 120 matches the expected data, as provided by the pattern generator 350. An error counter 140 maintains count of the errors detected by the comparator 250.

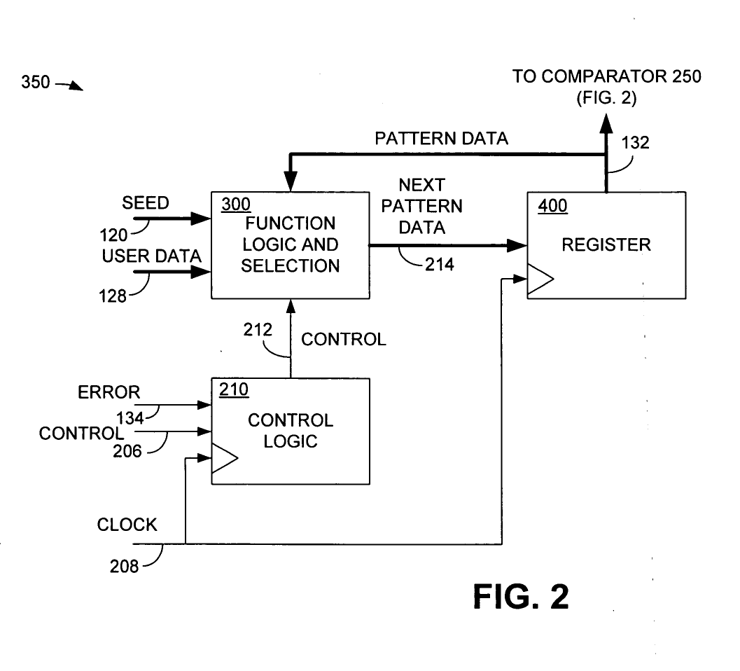

FIG. 2 is a block diagram illustrating the pattern generator 350 of FIG. 1. The pattern generator 350 can use its current state as well as external inputs for generating the next set of pattern bits. The pattern generator 200 in the transceiver 110 is similarly configured. The pattern generator 350 comprises a function logic and selection element 300, a control logic 210 and a register 400. Parallel pattern data is shown using heavy arrows while control information is shown using thin arrows. The seed data for the pattern generator 350 is supplied via connection 120 and the user data is supplied via connection 128. For the pattern generator 200 in a transmitter, the seed data is supplied from the connection 124 (FIG. 1) and the user data is supplied from connection 126 (FIG. 1). The output of the function logic and selection element 300 is the next pattern data on connection 214, which is supplied to the register 400.

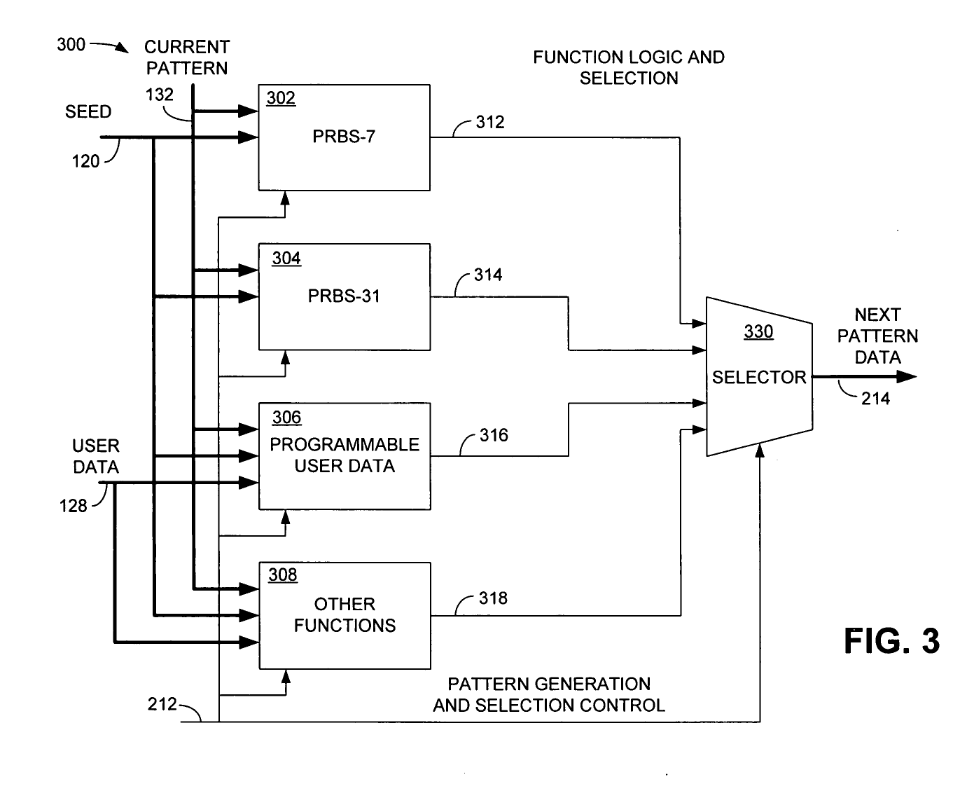

An error input is supplied via connection 134 and a control command is supplied via connection 206 to the control logic 210. A clock signal is supplied via connection 208 to the control logic 210 and to the register 400. The control logic 210 delivers a control signal via connection 212 to the function logic and selection element 300, the operation of which will be described in greater detail in FIG. 3. The output of the register 400 via connection 132 is supplied both as feedback to the function logic and selection element 300 and as input to the comparator 250 (FIG. 1). As will be described in greater detail below, the register 400 comprises, in one embodiment, four 10-bit registers, which can be configured in various ways, depending upon the desired functionality of the pattern generator 350. The information fed back from the register 400 to the function logic and selection element 300 allows for patterns of sufficient length to test high data rate communication channels to be generated using minimal logic. The size of the register 400 depends on the type of patterns to be generated. For example, to generate a 31-bit PRBS pattern, i.e., a PRBS pattern based on the “x31+x28+1” polynomial, the register 400 would comprise a minimum of 31 bits.

The function logic and selection element 300 assembles data from multiple sources (e.g., seed data on connection 120 and user data on connection 128) and generates the next set of pattern bits for the pattern sequence used. For example, the next pattern data on connection 214 may be a function of both the current pattern data and the incoming “seed” data.

The control logic 210 determines the type of pattern that the pattern generator 350 will generate, and determines when new patterns will be loaded. For example, the pattern generator 350 in the receiver might use the result of the comparator 250 on connection 134 to reload the pattern generator 350 to obtain synchronization with the transmitter if the comparator 250 indicates that the pattern on connection 132 is no longer synchronized with the incoming data on connection 120.

FIG. 3 is a block diagram illustrating the function logic and selection element 300 of FIG. 2. The function logic and selection element 300 includes a PRBS-7 pattern generator 302, a PRBS-31 pattern generator 304, and a programmable user data element 306. Additional pattern generation functions could also be included, as represented by block 308, which may represent an additional PRBS function or a different user data pattern function.

The seed data on connection 120 and the current pattern data on connection 132 is supplied to each of the blocks of the function logic and selection element 300. User data on connection 128 is supplied to the programmable user data element 306. The function block 308 may use a variety of inputs, such as seed data, current pattern data or can receive user data similar to the programmable user data block 306. Control signals from the control logic 210 of FIG. 2 are supplied via connection 212 to each of the elements. The output of the PRBS-7 pattern generator 302 via connection 312, the output of the PRBS-31 pattern generator 304 on connection 314, the output of the programmable user data element 306 on connection 316 and the output of the other functions block 308 on connection 318 are supplied to the selector 330. The selector 330 receives a control signal via connection 212 and determines which output will be provided as the next pattern data on connection 214 (see FIG. 2).

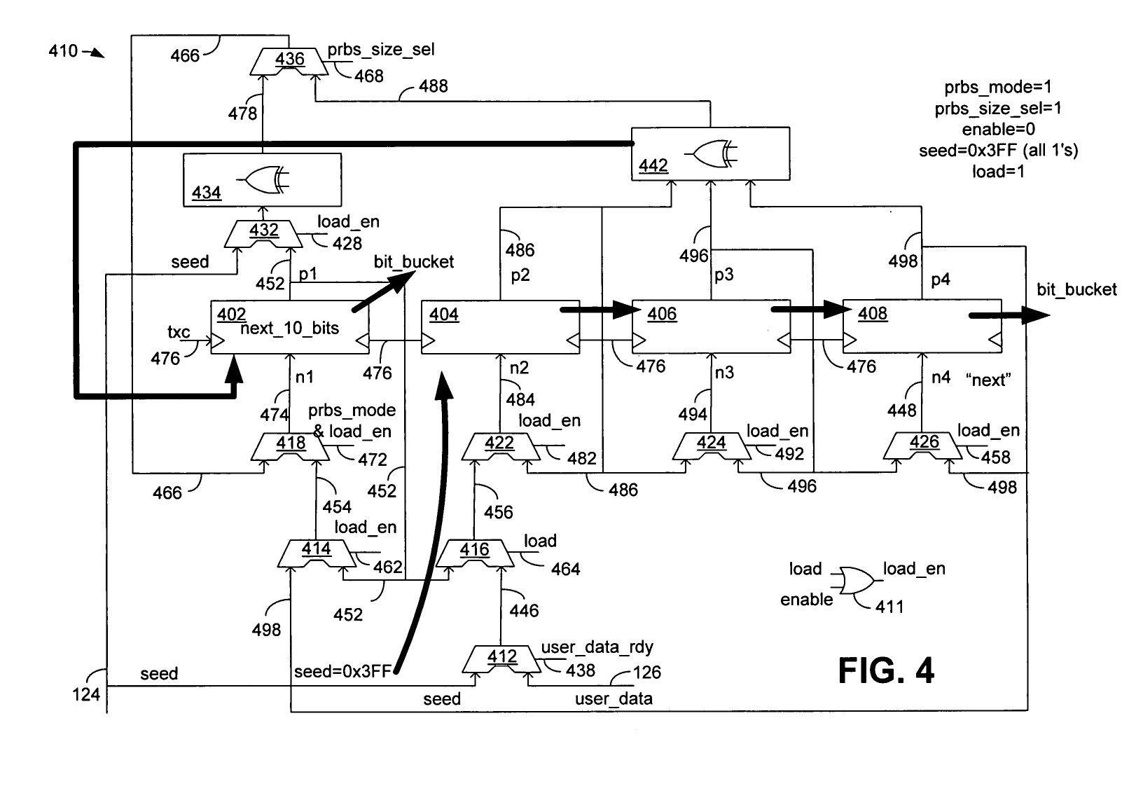

FIGS. 4 through 10 describe a particular embodiment of the register 400 and the function logic and selection element 300 of FIG. 2 operating under different modes of operation. For example, the register 400 and the function logic and selection element 300 of FIG. 2 can be configured differently, depending on whether they are located in the transmitter or the receiver, and depending on the desired functionality. For example, the register 400 and the function logic and selection element 300 can be configured to provide a PRBS-31 pattern generator, or can be configured to load any arbitrary fixed length user defined test pattern. The implementation shown in FIGS. 4 through 10 is useful in implementations where data is serialized/deserialized using 10 bits at a time. That is, this circuitry is designed to operate at a frequency 10 times slower than the bit serial rate.

FIG. 4 is a block diagram illustrating the register 400 and the function logic and selection element 300 of FIG. 2 configured to load PRBS-31 pattern generator data in the transmitter. The logic and registers 410 in FIG. 4 comprises four 10-bit registers 402, 404, 406 and 408. The circuitry in the logic and registers 410 also comprises a plurality of multiplexers configured to load the registers based on various control signals. For example, the seed data on connection 124 is supplied to a first input of multiplexer 412 while user data via connection 126 is supplied to another input of the multiplexer 412. Depending on the value of the “user_data_rdy” signal on connection 438, either seed data or user data is supplied via connection 446 to one of the inputs of the multiplexer 416. Depending on the logic level of the “load” signal on connection 464, either the output of the multiplexer 412 or the output of the register 402 on connection 452 will be supplied via connection 456 to the multiplexer 422. Similarly, depending on the logic level of the “load_en” signal on connection 462, either the output of the register 402 on connection 452 or the output of register 408 on connection 498 will be supplied via connection 454 to the multiplexer 418. The “load_en” signal is the logical “OR” of the “load” and the “enable” signals as shown by the OR gate 411.

Depending on the logic level of the “prbs_mode & load_en” signal on connection 472, either the output of the multiplexer 414 on connection 454 or the output of the multiplexer 436 on connection 466 will be supplied via connection 474 to the register 402. Similarly, depending on the logic level of the “load_en” signal on connections 482, either the output of the register 404 on connection 486, or the output of the multiplexer 416 on connection 456 will be supplied to the register 404.

Similarly, depending on the logic level of the “load_en” signal on connections 492, either the output of the register 406 on connection 496, or the output of the register 404 on connection 486 will be supplied to the register 406. Similarly, depending on the logic level of the “load_en” signal on connections 458, either the output of the register 408 on connection 498, or the output of the register 406 on connection 496 will be supplied to the register 408.

The output of the register 402 is supplied via connection 452 to a first input of the multiplexer 432. Depending on the logic level of the “load_en” signal on connection 428, either the output of the register 402 or the value of the seed data on connection 124 will be supplied by the multiplexer 432 to the exclusive (XOR) function 434. While shown as a single gate, the XOR function 434 comprises 10 two input XOR gates in this embodiment based on the PRBS-7 polynomial to predict the next 10 bits for the 10-bit register 402. Similarly, the output of the register 404 on connection 486, the output of the register 406 on connection 496, and the output of the register 408 on connection 498 is supplied to the XOR function 442. It should be noted that the XOR function 442 is implemented as 10 two input XOR gates based on the PRBS-31 polynomial for predicting the next 10 bits of the PRBS-31 pattern.

The output of the XOR function 434 is supplied via connection 478 to the multiplexer 436 while the output of the XOR function 442 is supplied via connection 488 to the multiplexer 436. Depending on the logic level of the “prbs_size_sel” signal on connection 468, either the output of the XOR function 434, or the output of the XOR function 442 is supplied via connection 466 to the multiplexer 418.

In FIG. 4, the logic and registers 410, and specifically, the register 404 is seeded using a non-zero value via connection 124. In this example, the register 404 is seeded with the value 0x3FF. The PRBS-31 pattern generator uses 31 of the 40 available flip-flops in the registers 402, 404, 406 and 408. To predict the next 10 bits, the output of registers 404, 406 and 408 is fed back via the XOR function 442 through multiplexers 436 and 418 to register 402. In this manner, the logic and registers 410 sequences to the next pattern based on the currently loaded value. The data in registers 404 and 406 are fed forward through multiplexers 424 and 426 to registers 406 and 408. Register 404 is loaded with the non-zero seed data through multiplexers 412, 416, and 422. After three cycles in the load mode, the upper register banks (registers 404, 406 and 408) will be loaded with all logic 1's given that the seed value is all logic 1's. This condition will predict all logic 0's going into the first register 402. It is this predictive nature of the first register 402 that suggests that the seed data be initially loaded into the second register 404 rather than into the first register 402.

The heavy arrows indicate the direction that the data moves between the register banks (402, 404, 406 and 408) with each clock cycle. The data from register 404 moves into register 406. Similarly, the data from register 406 moves to register 408. The data from registers 402 and 408 are no longer needed for the PRBS-31 function after use and are simply discarded (i.e., sent to what is referred to as a “bit_bucket”) on the next clock cycle.

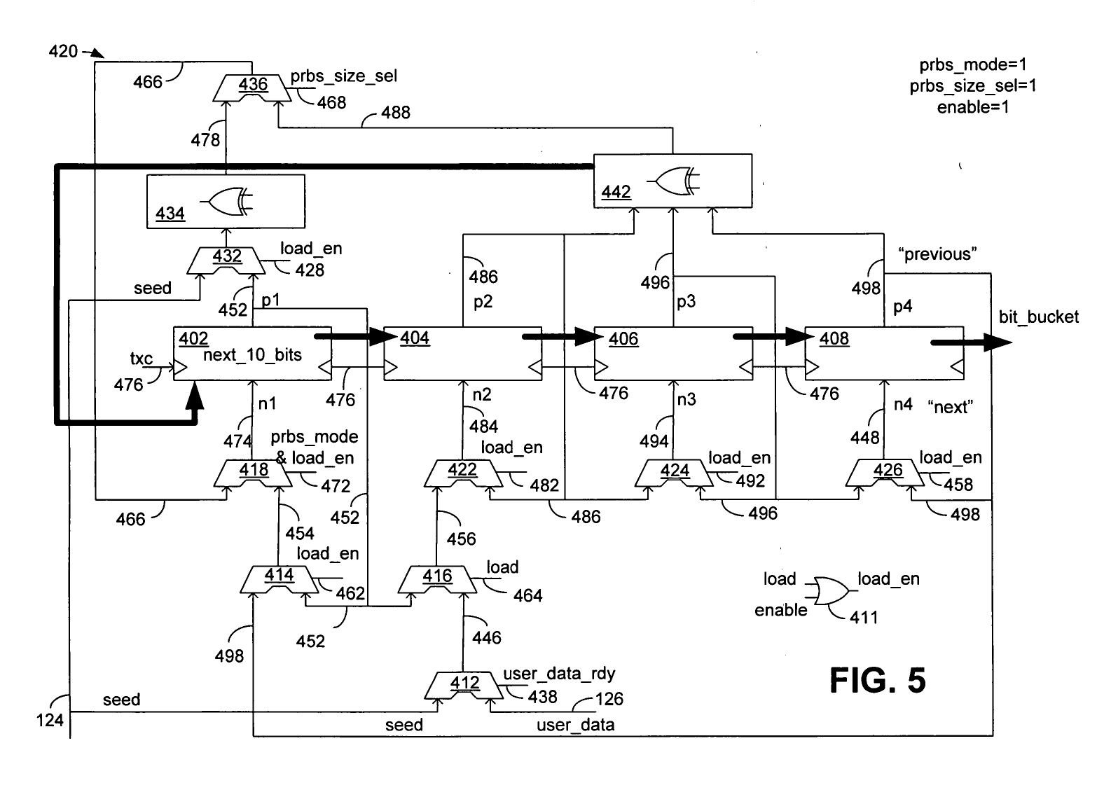

FIG. 5 is a block diagram illustrating the register 400 and the function logic and selection element 300 of FIG. 2 configured to “run” the data loaded in FIG. 4. In FIG. 5, once the PRBS-31 pattern generator is loaded with a non-zero value, it is switched to the run mode. This is done by removing the “load” signal and setting the “enable” signal. When in PRBS-31 pattern generation mode, the data shifts to the right as indicated by the heavy arrows connecting the registers 402, 404, 406 and 408. The registers 404, 406, and 408 provide data to the XOR function 442 to predict the next 10-bits. It should be noted that in the run mode the data from register from 402 is sent to register 404 on the next clock cycle as register 404 is no longer being loaded from the seed data. The data from the register 402 is also sent to the parallel to serial coder 112 (FIG. 1) for the transmit pattern generator 200. In a similar manner for the receiver pattern generator 350, the circuit is “seeded” or loaded with the data from the serial to parallel decoder 116 (FIG. 1). After the receiver's pattern generator 350 has been loaded, it can be switched to run mode and the comparator 250 (FIG. 1) will be able to compare the incoming data from the serial to parallel decoder 116 with the predicted bits from the pattern generator 350.

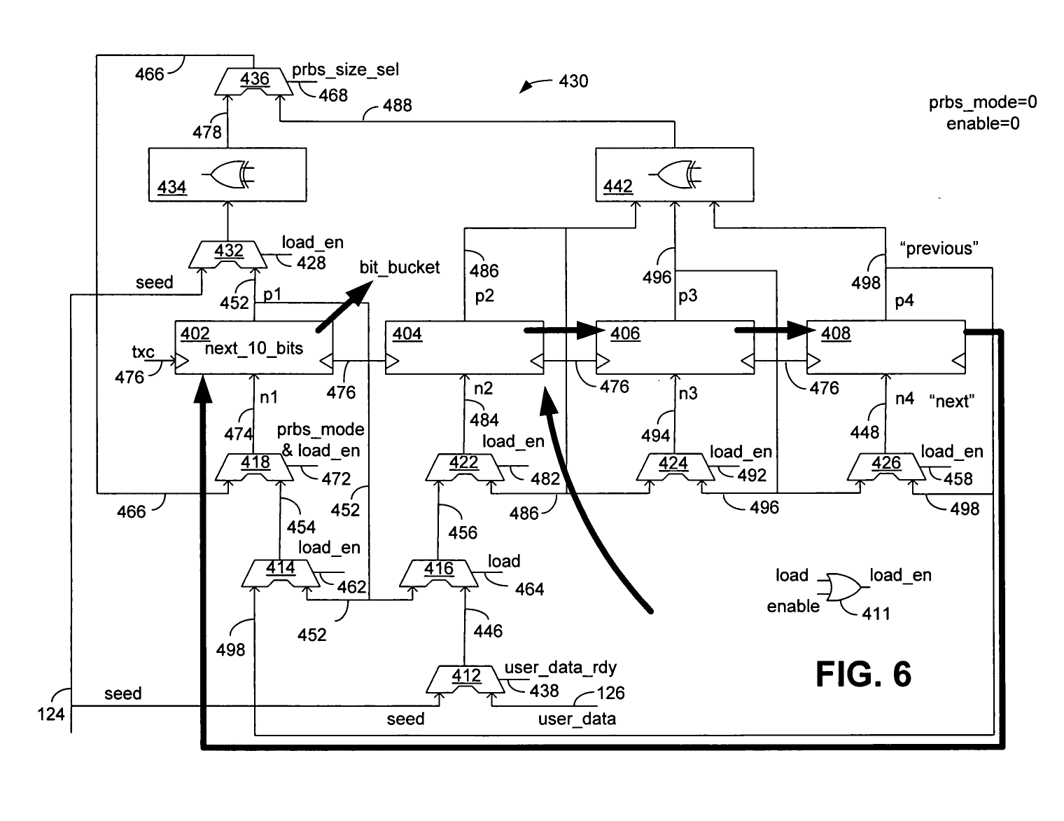

FIG. 6 is a block diagram illustrating the register 400 and the function logic and selection element 300 of FIG. 2 configured to load user defined fixed length data in the transmitter. While any fixed length user defined data may be used, the following example will use 40-bit user data. The use of 40-bit user data is enabled because of the availability of the four 10-bit registers 402, 404, 406 and 408. User data is loaded via connection 126 into the register 404 as a sequence of four 10-bit words, as indicated using the heavy arrow. The use of a 40-bit user data pattern simplifies the task of studying data pattern sensitivities. To minimize the amount of circuitry, the 40-bit user defined data is loaded in this implementation 10-bits at a time. The register 402 is used to provide or predict the next 10 bits. The 10-bit registers 402, 404, 406, and 408 shift 10 bits each time an additional 10 bits are added. When the data in register 408 is shifted into register 402, it is important to get only one “load” cycle when the new data is presented. Otherwise, after four clock cycles, the same new data would be loaded into all four registers. To prevent this, additional logic (not shown) generates one “load” cycle on a logic 0 to logic 1 bit transition when the “user_data_rdy” signal is logic 1. In this manner, the register 430 loads to any arbitrary 40-bit user defined test pattern.

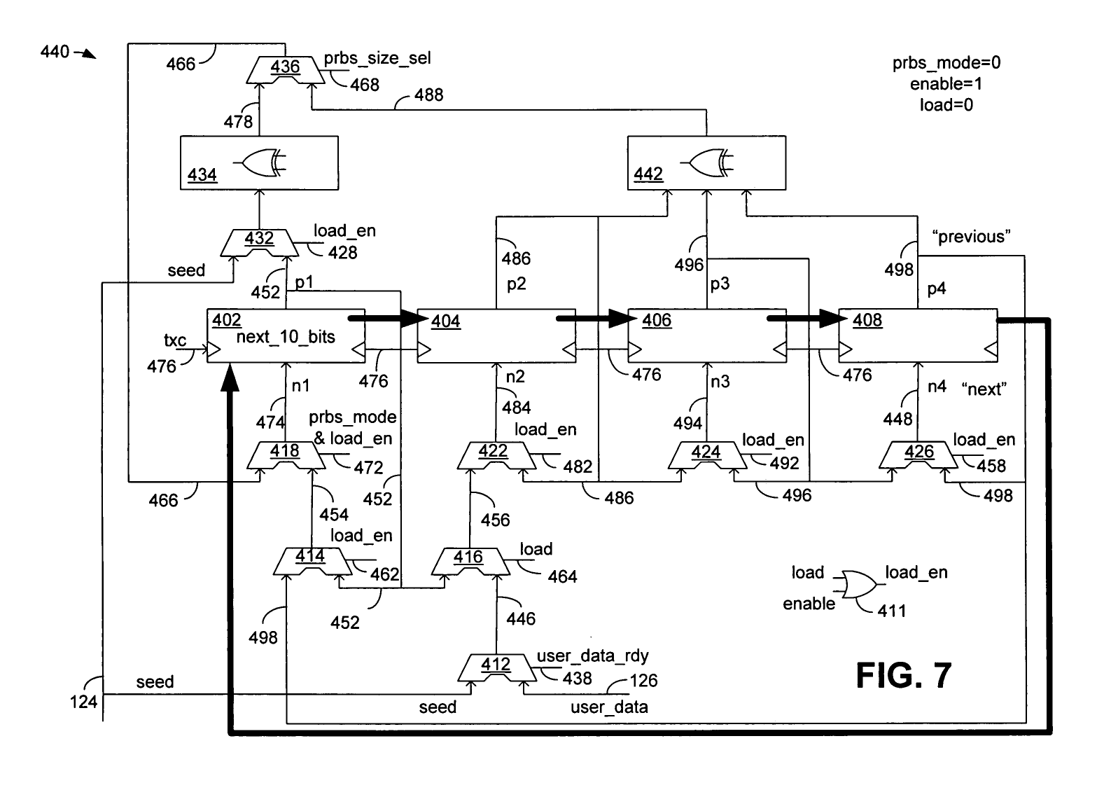

FIG. 7 is a block diagram illustrating the register 400 and the function logic and selection element 300 of FIG. 2 configured to run the user defined fixed length data loaded in FIG. 6. After the 40-bit pattern has been loaded (FIG. 6) the circuit 440 is switched into run mode by making the “enable” signal logic high. In this mode, the circuit 440 essentially becomes a cyclic 40-bit shift register, shifting 10-bits at a time. The 10-bits from register 402 are delivered to the parallel to serial coder 112 (FIG. 1). The receiver's pattern generator 350 can be loaded and enabled similar to the transmitter's pattern generator 200 by using user data to load the pattern in the generator and then enabling the pattern to circulate.

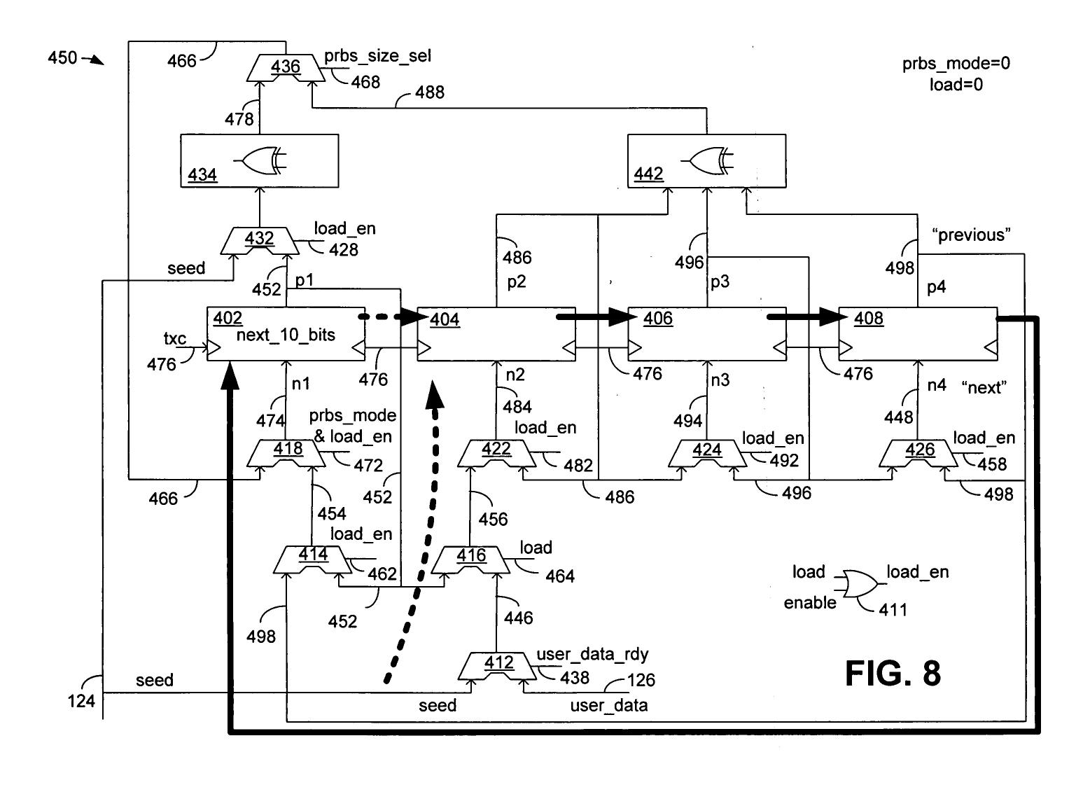

FIG. 8 is a block diagram illustrating the register 400 and the function logic and selection element 300 of FIG. 2 in an alternative embodiment that can be used in the receiver pattern generator 350. The embodiment shown in FIG. 8 makes use of the seeding capability in a manner similar to that for PRBS patterns. Instead of loading data in through the user_data path 126, data from the serial to parallel decoder 116 (FIG. 1) is supplied to the circuit 450 through the “seed” path 124, as shown using the dotted arrow from the seed path to the register 404. After loading for four clock cycles, registers 402, 404, 406, and 408 will have been loaded with a 40-bit pattern that can be used to compare whether the next 40 bits are an exact match. In the run mode, as shown by the dotted arrow between register 402 and 404, the 40 bit pattern will continually cycle.

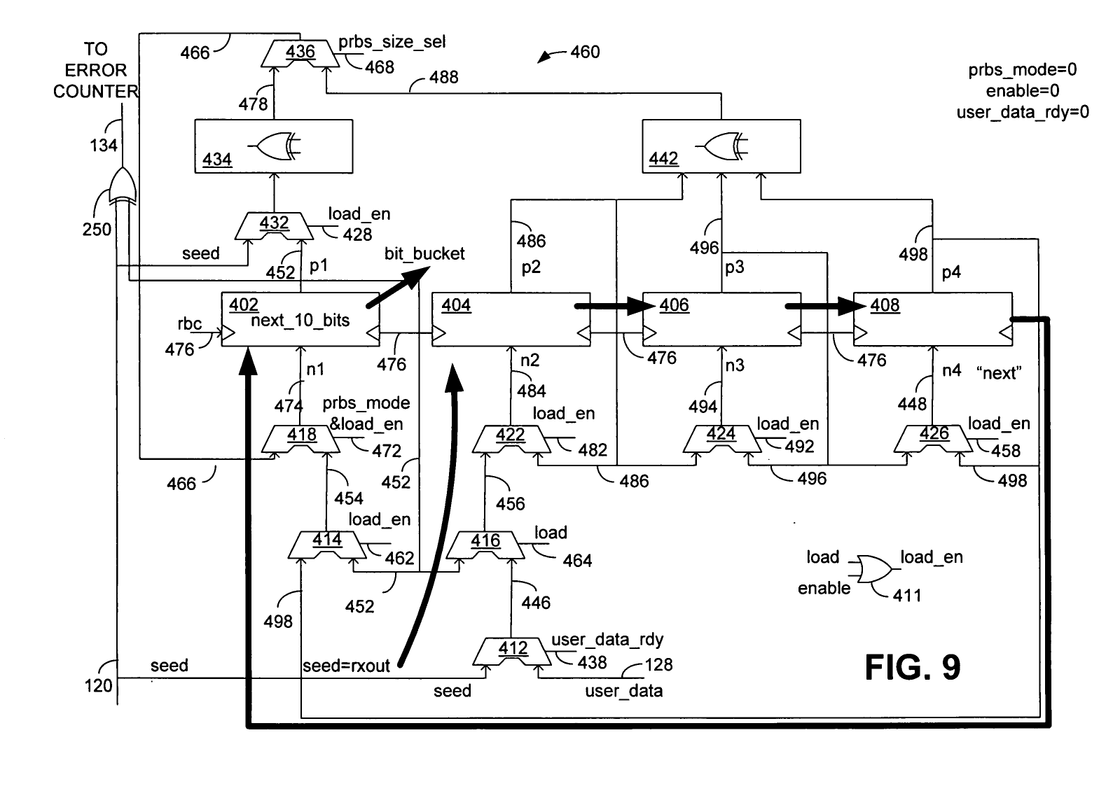

FIG. 9 is a block diagram illustrating the register 400 and the function logic and selection element 300 of FIG. 2 configured with the comparator of FIG. 1 in a user defined 40-bit “load to error” mode in the receiver. It is desirable during testing to compare the incoming receiver output data, “rxout,” on connection 120 with what a predicted word should be. As shown, the 10-bit register 404, is seeded with the receiver's output data “rxout” from the serial to parallel decoder 116 (FIG. 1) on connection 120. After four clock cycles, the entire 40-bit pattern has been loaded into the four 10-bit registers 402, 404, 406 and 408. The data has been shifted such that the first word loaded into the register 404 is in register 402 and can be compared with the next new word (which should be the same as the word four clock cycles prior). Thus, if the pattern being sent by the transmit generator is “ABCD . . . ,” the receiver will load with the same pattern and can predict and check for errors in the incoming data pattern. In this manner, the circuitry 460 of FIG. 9 can be self-seeded, loaded, and used to compare the received word to any arbitrary 40-bit user defined pattern. The four 10 bit words are circulated through the registers 402, 404, 406 and 408 and then compared in the comparator 250 with the next 10 incoming bits from connection 120.

Using the self-seeding capability described above for the PRBS mode and the 40-bit user defined data mode allows the capture of received data when an error is detected. This is referred to as a “load-until-error” feature. In this mode, the circuit of FIG. 9 is continuously seeded with the “rxout” data. When an error is detected, the data in the registers 402, 404, 406 and 408 is suspended from being advanced and is available for analysis to determine the cause of the error. The load until error feature causes the “load” signal on connection 464 to remain at a logic high until an error is detected, such as a data mismatch detected by the data comparator 250. When an error is detected, the incoming word is shifted into register 404 and a signal is sent to an error counter. After the error is detected, the load signal is removed from connection 464 and the register 460 stops circulating. At this point, the data can be read out of the registers 402, 404, 406 and 408 and the last four words received when the error was detected can be determined. The load until error feature capability exists because of the ability to self seed for both the PRBS mode and the 40-bit user defined data mode. In the load until error mode, the receiver pattern generator is continually seeded using the input on connection 120 rather than seeding and then using the recycle data.

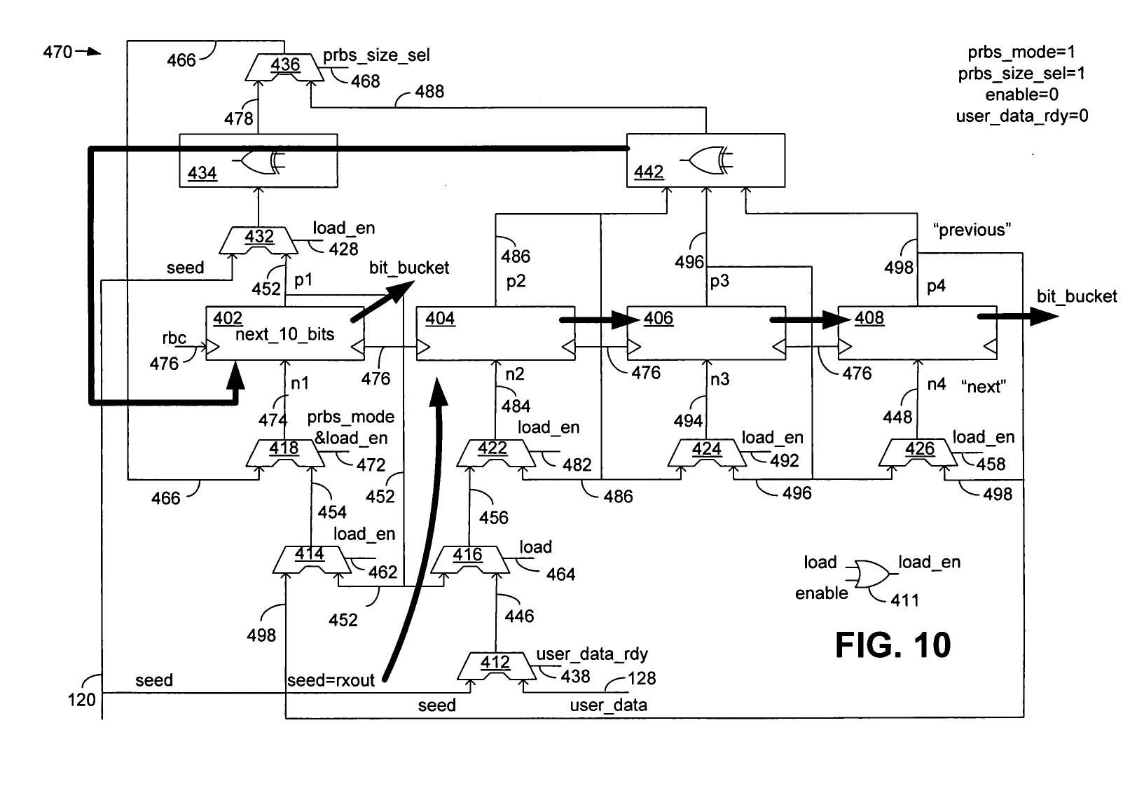

FIG. 10 is a block diagram illustrating the register 400 and the function logic and selection element 300 of FIG. 2 configured to run PRBS-31 pattern data in a “load till error” mode in the receiver. The circuitry 470 uses three clock cycles to seed the registers 402, 404, 406, and 408. After three clock cycles, the registers 404, 406 and 408 will be loaded. These three registers are used to generate the next predicted value that is located into register 402 as shown using the output of the XOR function 442.

While various embodiments of the invention have been described, it will be apparent to those of ordinary skill in the art that many more embodiments and implementations are possible that are within the scope of this invention.

1. A multiple function pattern generator for a serializer/deserializer circuit located on an integrated circuit (IC), comprising:
a pattern generator in a communications channel, the pattern generator configured to develop a plurality of test patterns and configured to receive the output of the communications channel and user data based on pattern selection and user data; and
a comparator configured to receive the output of the communication channel and the output of the pattern generator, where the pattern generator self seeds with the user data, and where the user data comprises a fixed length bit test pattern.

2. The multiple function pattern generator of claim 1, further comprising:
a plurality of registers associated with the pattern generator, where the plurality of registers loads sequentially with the user data.

3. The multiple function pattern generator of claim 2, wherein the plurality of registers comprises a plurality of 10 bit registers.

4. The multiple function pattern generator of claim 2, wherein the comparator continually compares the fixed length bit test pattern with the output of the communication channel.

5. The multiple function pattern generator of claim 2, wherein the plurality of registers loads with the output of the communication channel until an error is detected.

6. The multiple function pattern generator of claim 5, wherein the error is supplied to an error counter.

7. A method for generating test patterns in an integrated circuit (IC), comprising:
receiving seed data and user data from a serial communication channel;
generating a user defined fixed length bit test pattern; and
comparing the seed data against the user defined fixed length bit test pattern to determine whether the seed data matches the user defined fixed length bit test pattern.

8. The method of claim 7, further comprising self-seeding the user defined fixed length bit test pattern.

9. The method of claim 7, wherein the seed data is serial communication data and the integrated circuit is a serializer/deserailizer circuit.

10. The method of claim 7, where the self seeding user defined fixed length bit test pattern is loaded into a plurality of registers; and further comprising sequentially loading the plurality of registers with the self seeding user defined fixed length bit test pattern.

11. The method of claim 10, further comprising continually comparing the user defined fixed length bit test pattern with the output of the serial communication channel.

12. The method of claim 11, further comprising loading the plurality of registers with the output of the serial communication channel until an error is detected.

13. The method of claim 12, further comprising supplying the error to an error counter.

14. A multiple function pattern generator for a serializer/deserializer circuit located on an integrated circuit (IC), comprising:
a first pattern generator in a communications channel, the first pattern generator capable of transmitting various test patterns based on pattern selection and user data;
a second pattern generator configured to receive the output of the communication channel as seed data, and configured to receive user data; and
a comparator configured to receive the output of the communication channel and the output of the second pattern generator, where the second pattern generator self seeds with the user data, and where the user data comprises a fixed length bit test pattern.

15. The multiple function pattern generator of claim 14, further comprising:
a plurality of registers associated with the pattern generators, where the plurality of registers loads sequentially with the user data.

16. The multiple function pattern generator of claim 15, wherein the plurality of registers comprises a plurality of 10 bit registers.

17. The multiple function pattern generator of claim 15, wherein the comparator continually compares the fixed length bit test pattern with the output of the communication channel.

18. The multiple function pattern generator of claim 15, wherein the plurality of registers loads with the output of the communication channel until an error is detected.

19. The multiple function pattern generator of claim 18, wherein the error is supplied to an error counter.
